(19) United States
(12) Patent Application Publication
(10) Pub. No.: US 2025/0298062 A1
(43) Pub. Date: Sep. 25, 2025

(54) VOLTAGE DETECTION CIRCUIT

(71) Applicants: DENSO CORPORATION, Kariya-city (JP); TOYOTA JIDOSHA KABUSHIKI KAISHA, Toyota-shi (JP); MIRISE Technologies Corporation, Nisshin-shi (JP)

(72) Inventors: SHOTARO WADA, Nisshin-shi (JP); SOYA TANIGUCHI, Nisshin-shi (JP); YOSHIKAZU FURUTA, Nisshin-shi (JP); TOMOHIRO NEZUKA, Nisshin-shi (JP)

(21) Appl. No.: 18/971,143

(22) Filed: Dec. 6, 2024

(30) Foreign Application Priority Data
Mar. 25, 2024 (JP) 2024-047796

(51) Int. Cl. G01R 19/25

(52) U.S. Cl. CPC G01R 19/25

(57) ABSTRACT

A voltage detection circuit includes an AD converter, an input chopper circuit, an output chopper circuit, a digital low-pass filter, and a current chopper circuit. The chopper circuit switch a connection state of each input terminal of the AD converter, first and second input wirings at a first frequency. The output chopper circuit alternately execute inverting and non-inverting operations for an output value of the AD converter. The digital low-pass filter removes a high-frequency component from the output value of the output chopper circuit and operates at an output frequency. The current chopper circuit switches the connection state of a first current source, the first input wiring, a second current source and the second input wiring at a second frequency.

### CROSS REFERENCE TO RELATED APPLICATION

This application is based on Japanese Patent Application No. 2024-047796 filed on Mar. 25, 2024, the disclosure of which is incorporated herein by reference.

### TECHNICAL FIELD

The present disclosure relates to a voltage detection circuit.

### BACKGROUND

In a related field, a voltage detection circuit may detect disconnection on the analog circuit side in an AD converter (Analog-to-Digital converter) that converts an input voltage into a digital value. In the above-mentioned circuit, the potential at the input terminal of the AD converter is pulled up or pulled down, and the disconnection is detected based on the output value of the AD converter at that time.

### SUMMARY

The present disclosure describes a voltage detection circuit including an AD converter, first and second input wirings, an input chopper circuit, a digital low-pass filter, first and second current sources, and a current chopper circuit.

### BRIEF DESCRIPTION OF DRAWINGS

FIG. 1 is a circuit diagram of a voltage detection circuit according to a first embodiment.

FIG. 2 is a graph illustrating respective voltages during an operation of the voltage detection circuit according to the first embodiment.

FIG. 3 is a circuit diagram of a voltage detection circuit according to a second embodiment.

FIG. 4 is a graph illustrating respective voltages during an operation of the voltage detection circuit according to the second embodiment.

### DETAILED DESCRIPTION

In an AD converter of a voltage detection circuit in a related field, since an input voltage of the AD converter may change during a disconnection detection operation, it may be necessary to suspend the detection operation of a target voltage during the disconnection detection operation.

According to an aspect of the present disclosure, a voltage detection circuit includes an AD converter, a first input wiring, a second input wiring, an input chopper circuit, an output chopper circuit, a digital low-pass filter, a first current source, a second current source, and a current chopper circuit. The AD converter has a first input terminal and a second input terminal. The AD converter converts a voltage applied between the first input terminal and the second input terminal to a digital value. The input chopper circuit executes a switchover between a first connection state and a second connection state at a first frequency. In the first connection state, the first input wiring is connected to the first input terminal, and the second input wiring is connected to the second input terminal. In the second connection state, the first input wiring is connected to the second input terminal, and the second input wiring is connected to the first input terminal. The output chopper circuit alternately executes an inverting operation and a non-inverting operation at the first frequency. In the inverting operation, an output value of the AD converter is inverted and then output. In the non-inverting operation, the output value of the AD converter is output without inverting the output value. The digital low-pass filter removes a high-frequency component from the output value of the output chopper circuit and to be operated at an output frequency. The current chopper circuit executes a switchover between a third connection state and a fourth connection state at a second frequency. In the third connection state, the first current source is connected to the first input wiring, and the second current source is connected to the second input wiring. In the fourth connection state, the first current source is connected to the second input wiring, and the second current source is connected to the first input wiring. The first frequency is equal to the output frequency multiplied by two raised to power of m, where m is an integer greater than or equal to zero. The second frequency is equal to the output frequency multiplied by two raised to power of n, where n is an integer greater than or equal to zero. The integer of n is greater than or equal to the integer of m.

In this voltage detection circuit, the first input wiring and the second input wiring are connected to the voltage detection target device. The voltage between the first input wiring and the second input wiring is converted into a voltage fluctuating at the first frequency fc1 by the input chopper circuit, and then provided to the AD converter. The AD converter outputs the input voltage (i.e., the voltage fluctuating at the first frequency fc1) as a digital value. The output chopper circuit restores the waveform corresponding to the original voltage (i.e., the voltage between the first input wiring and the second input wiring) by inverting the output value of the AD converter (i.e., the voltage fluctuating at the first frequency fc1) at predetermined intervals at the first frequency fc1. The digital low-pass filter removes high-frequency components from the output value of the output chopper circuit. According to this configuration, the low-frequency noise generated by the AD converter is modulated to a high frequency by the output chopper circuit, and this high-frequency voltage is removed by the digital low-pass filter. Therefore, errors due to low-frequency noise can be suppressed. Additionally, in this voltage detection circuit, current is supplied to the first input wiring and the second input wiring from the first current source and the second current source. By the operation of the current chopper circuit, the supplied current of the first current source and the supplied current of the second current source flow alternately to the first input wiring and the second input wiring. When there is no disconnection between the first input wiring and the second input wiring, an offset voltage occurs between the first input wiring and the second input wiring due to the error between the current supplied from the first current source and the current supplied from the second current source. Since the current chopper circuit switches the connection state at the second frequency fc2, the offset voltage becomes a voltage that fluctuates at the second frequency fc2. The offset voltage is provided to the digital low-pass filter through the input chopper circuit, AD converter, and output chopper circuit. The offset voltage that fluctuates at a high frequency is removed by the digital low-pass filter. Therefore, the voltage to be detected can be accurately measured while suppressing the influence of the offset voltage. In particular, by satisfying the relationship fc1=fd×2^{m}, fc2=fd×2ⁿ, where n≥m, the digital low-pass filter can appropriately remove voltages with the first frequency fc1 and the second frequency fc2. Therefore, according to this voltage detection circuit, the voltage to be detected can be measured more accurately. Additionally, if a disconnection occurs in the first input wiring, the current supplied from the current chopper circuit to the first input wiring will no longer flow to the voltage detection target device side, causing the potential of the first input wiring to rise. If a disconnection occurs in the second input wiring, the current supplied from the current chopper circuit to the second input wiring will no longer flow to the voltage detection target device, causing the potential of the second input wiring to rise. Therefore, the disconnection can be detected from the potentials of the first input wiring and the second input wiring. As explained above, according to this voltage detection circuit, it is possible to perform a disconnection detection operation in parallel with the voltage detection operation, and accurately detect the target voltage.

### First Embodiment

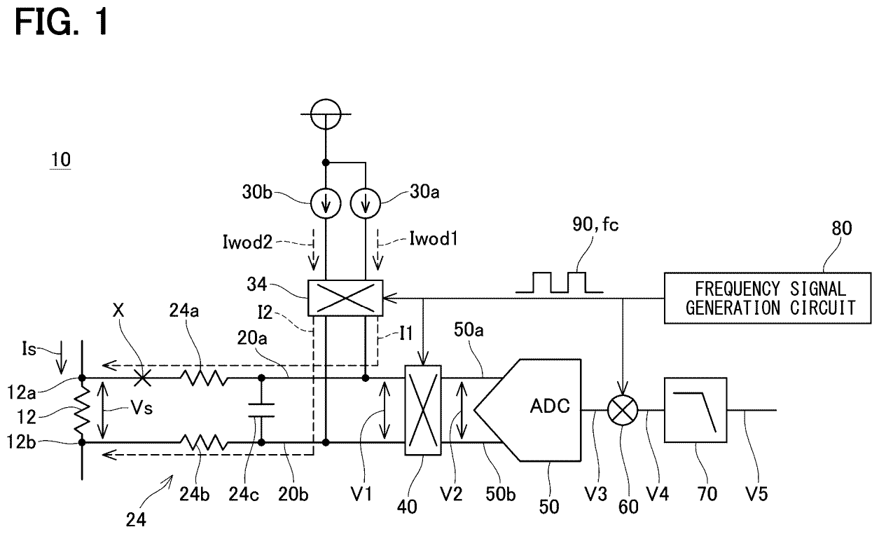

A voltage detection circuit 10 according to a first embodiment shown in FIG. 1 includes a shunt resistor 12. The shunt resistor 12 is connected to an external circuit (not shown). A current Is supplied from an external circuit flows through the shunt resistor 12. The voltage detection circuit 10 detects the current Is by detecting the voltage Vs between both ends of the shunt resistor 12.

The voltage detection circuit 10 includes a first input wiring 20a, a second input wiring 20b, and an anti-aliasing filter 24 (hereinafter referred to as AAF 24). The first input wiring 20a and the second input wiring 20b are connected to the shunt resistor 12 via the AAF 24. The AAF 24 has a first resistor 24a, a second resistor 24b, and a capacitor 24c. The first input wiring 20a is connected to one terminal 12a of the shunt resistor 12 (more specifically, the high-potential side terminal) via the first resistor 24a. The second input wiring 20b is connected to the other terminal 12b of the shunt resistor 12 (more specifically, the low-potential side terminal) via the second resistor 24b. Therefore, the shunt resistor 12 is connected between the first input wiring 20a and the second input wiring 20b via the first resistor 24a and the second resistor 24b. The electrical resistance of the first resistor 24a is equal to that of the second resistor 24b. The capacitor 24c is connected between the first input wiring 20a and the second input wiring 20b.

The voltage detection circuit 10 includes a frequency signal generation circuit 80. The frequency signal generation circuit 80 outputs a pulse signal 90 with a duty cycle of 50% oscillating at a frequency fc. The pulse signal 90 is provided to each chopper circuit, which will be described later.

The voltage detection circuit 10 includes a first current source 30a, a second current source 30b, and a current chopper circuit 34. The first current source 30a generates a constant DC current Iwod1. The second current source 30b generates a constant DC current Iwod2. The respective output terminals of the first current source 30a and the second current source 30b are connected to the current chopper circuit 34.

The current chopper circuit 34 changes the mutual connection state between the first current source 30a, the second current source 30b, the first input wiring 20a, and the second input wiring 20b. The current chopper circuit 34 alternately switches the connection state between a connection state A and a connection state B. In the connection state A, the output terminal of the first current source 30a is connected to the first input wiring 20a, and the output terminal of the second current source 30b is connected to the second input wiring 20b. Therefore, in the connection state A, the current Iwod1 flows through the first input wiring 20a, and the current Iwod2 flows through the second input wiring 20b. In the connection state B, the output terminal of the first current source 30a is connected to the second input wiring 20b, and the output terminal of the second current source 30b is connected to the first input wiring 20a. Therefore, in the connection state B, the current Iwod1 flows through the second input wiring 20b, and current Iwod2 flows through the first input wiring 20a. The current chopper circuit 34 receives the pulse signal 90 output by the frequency signal generation circuit 80. The current chopper circuit 34 alternately switches the connection state between the connection state A and the connection state B in synchronization with the pulse signal 90. Therefore, the current chopper circuit 34 alternately switches the connection state between the connection state A and the connection state B at a frequency fc. Additionally, since the duty cycle of the pulse signal 90 is 50%, the duration of the connection state A and the connection state B are equal in each cycle.

As shown in FIG. 1, the current 11 (i.e., current Iwod1 or current Iwod2) supplied from the current chopper circuit 34 to the first input wiring 20a flows to the external circuit via the first resistor 24a and the shunt resistor 12. Additionally, the current I2 (i.e., current Iwod1 or current Iwod2) supplied from the current chopper circuit 34 to the second input wiring 20b flows to the external circuit via the second resistor 24b. As mentioned above, the electrical resistances of the first and second resistors 24a and 24b are equal to each other. Hereafter, the electrical resistance of the first and second resistors 24a and 24b are denoted as electrical resistance R. The electrical resistance of the shunt resistor 12 is much smaller than the electrical resistances R of the first and second resistors 24a and 24b. Since the current I1 flows through the first resistor 24a, the potential of the first input wiring 20a becomes higher than the potential of the terminal 12a of the shunt resistor 12 by a voltage Va (=R×I1). Additionally, since the current I2 flows through the second resistor 24b, the potential of the second input wiring 20b becomes higher than the potential of the terminal 12b of the shunt resistor 12 by a voltage Vb (=R×I2). Therefore, a voltage V1 is applied between the first input wiring 20a and the second input wiring 20b, where V1=Vs+ΔV (where ΔV=Va−Vb). If Iwod1=Iwod2, then I1=I2, resulting in ΔV=0. However, in reality, there is an error between the current Iwod1 and the current Iwod2, so a voltage ΔV, which is caused by the difference between the current Iwod1 and the current Iwod2, is applied between the first input wiring 20a and the second input wiring 20b. In this way, a voltage that is offset by ΔV relative to the target detection voltage Vs is applied between the first input wiring 20a and the second input wiring 20b. In the following, the voltage ΔV is referred to as the offset voltage ΔV. Since the current chopper circuit 34 alternately switches the current Iwod1 and the current Iwod2 and supplies them to the first input wiring 20a and the second input wiring 20b, the direction of the offset voltage ΔV generated in the connection state A is opposite to the direction of the offset voltage ΔV generated in the connection state B. Therefore, the offset voltage ΔV alternates between positive and negative.

The voltage detection circuit 10 includes an input chopper circuit 40, an AD converter 50 (hereinafter referred to as ADC 50), an output chopper circuit 60, and a digital low-pass filter 70 (hereinafter referred to as DLPF 70). The first input wiring 20a and the second input wiring 20b are connected to the input chopper circuit 40. The ADC 50 has a first input terminal 50a and a second input terminal 50b. The first and second input terminals 50a and 50b are connected to the input chopper circuit 40. The input chopper circuit 40 changes the mutual connection state of the first input wiring 20a, second input wiring 20b, first input terminal 50a and second input terminal 50b. The input chopper circuit 40 alternates between a connection state C and a connection state D. In the connection state C, the first input wiring 20a is connected to the first input terminal 50a; and the second input wiring 20b is connected to the second input terminal 50b. In the connection state D, the first input wiring 20a is connected to the second input terminal 50b; and the second input wiring 20b is connected to the first input terminal 50a. Therefore, in the connection state C, the voltage V2 applied between the first input terminal 50a and the second input terminal 50b matches the voltage V1 between the first input wiring 20a and the second input wiring 20b. In the connection state D, the voltage V2 applied between the first input terminal 50a and the second input terminal 50b matches the voltage V1 between the first input wiring 20a and the second input wiring 20b, with the positive and negative sides reversed. The input chopper circuit 40 alternately switches the connection state between the connection state C and the connection state D in synchronization with the pulse signal 90 provided from the frequency signal generation circuit 80. Therefore, the input chopper circuit 40 alternately switches the connection state between the connection state C and the connection state D at the frequency fc. Additionally, since the duty ratio of the pulse signal 90 is 50%, the duration of the connection state C and the duration of the connection state D are equal in each cycle.

The ADC 50 outputs a signal that converts the voltage V2 applied between the first input terminal 50a and the second input terminal 50b into a digital value. In the following, the voltage indicated by the digital signal output by the ADC 50 is referred to as voltage V3. The voltage V3 includes the voltage V2 and the error component generated by the ADC 50.

The output chopper circuit 60 processes the voltage V3, which is in the form of a digital value output by the ADC 50. The output chopper circuit 60 alternately performs a non-inverting operation that outputs the voltage V3 as it is and an inverting operation that outputs the voltage V3 with its polarity reversed. The output chopper circuit 60 alternates between the non-inverting operation and the inverting operation in synchronization with the pulse signal 90 input from the frequency signal generation circuit 80. Therefore, the output chopper circuit 60 alternates between the non-inverting operation and the inverting operation at the frequency fc. Additionally, since the duty cycle of the pulse signal 90 is 50%, the length of the period during which the non-inverting operation is performed and the length of the period during which the inverting operation is performed are equal in each cycle. In the following, the voltage indicated by the digital signal output by the output chopper circuit 60 will be referred to as a voltage V4.

The DLPF 70 removes the high-frequency components from the voltage V4 output by the output chopper circuit 60. Specifically, the DLPF 70 calculates the average value of the voltage V4 over one period of the output frequency fd and outputs this average value as a voltage V5. Therefore, the DLPF 70 repeatedly outputs the voltage V5 at the output frequency fd. In this way, the DLPF 70 repeatedly calculates the average value of the voltage V4, and by doing so, it outputs the voltage V5, which has had the high-frequency components removed from the voltage V4. The output frequency fd is the value obtained by dividing the sampling frequency fs of the ADC 50 by a predetermined decimation ratio. In other words, the output frequency fd is lower than the sampling frequency fs. The frequency fc described above is lower than the sampling frequency fs and higher than the output frequency fd. In the first embodiment, fc is equal to fd.

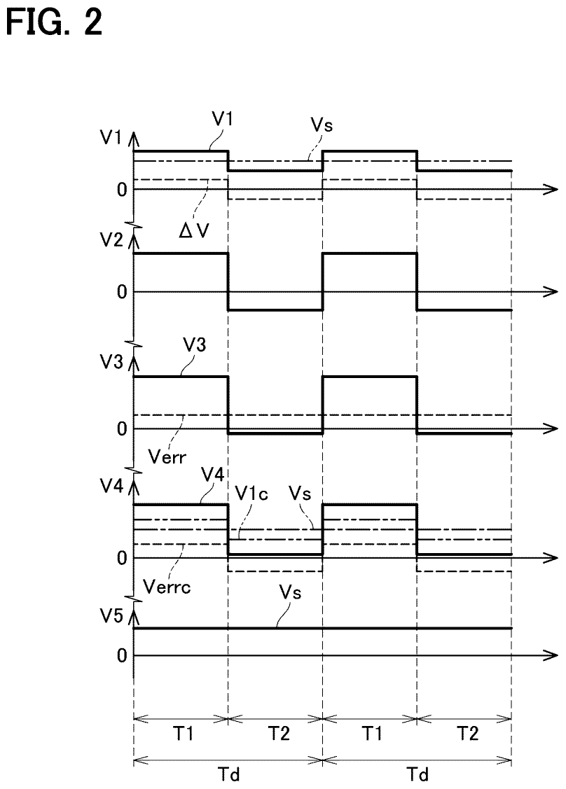

FIG. 2 illustrates the changes in voltages V1 to V5 during the normal operation of the voltage detection circuit 10. The rate of change of the voltage Vs is significantly lower compared to the rate of change of voltages V1 to V4. Therefore, in FIG. 2, the voltage Vs is shown as a constant value In FIG. 2, the period Td represents the duration of one cycle of the frequency Fd. In other words, Td is equal to 1/fd. Additionally, in FIG. 2, the period T1 corresponds to the first half of the period Td, while the period T2 corresponds to the second half of the period Td. The periods T1 and T2 are equal in length. As mentioned above, the voltage V1 applied between the input wirings 20a and 20b is given by V1=Vs+ΔV. As described above, the current chopper circuit 34 switches the current path at the frequency fc, so the offset voltage ΔV alternates between positive and negative at the frequency fc. Therefore, the voltage V1 fluctuates around the voltage Vs at the frequency fc.

As described above, the input chopper circuit 40 switches the connection state between the connection state C and the connection state D at the frequency fc. During the period T1, the connection state is in the connection state C, and during the period T2, the connection state is in the connection state D. As mentioned above, in the connection state C (i.e., period T1), the voltage V2 matches the voltage V1. Furthermore, in connection state D (i.e., during period T2), the voltage V2 matches the voltage V1 with its polarity reversed.

As mentioned above, the ADC 50 outputs a signal that converts the voltage V2 into a digital value. However, the output value of the ADC 50 has a certain error voltage Verr. The error voltage Verr is almost a DC component. Therefore, the voltage V3 indicated by the output value of ADC50 is the voltage V2 shifted by the error voltage Verr (i.e., V3=V2+Verr).

As mentioned above, the output chopper circuit 60 alternates between the non-inverting operation and inverting operation at the frequency fc. The output chopper circuit 60 performs the non-inverting operation during period T1 and inverting operation during period T2. In the non-inverting operation (i.e., period T1), the voltage V4 matches the voltage V3. Additionally, in the inverting operation (i.e., during period T2), the voltage V4 matches the voltage V3 with its polarity inverted. FIG. 2 also shows the voltage V1c and the error voltage Verrc, which make up the voltage V4. That is, V4=V1c+Verrc. The voltage V1c corresponds to the component of voltage V1, and the error voltage Verrc corresponds to the error voltage Verr. As shown in FIG. 2, the DC error voltage Verr is converted by the output chopper circuit 60 into the high-frequency error voltage Verrc that fluctuates at the frequency fc. Additionally, by synchronizing the non-inverting and inverting operations of the output chopper circuit 60 with the pulse signal 90, the voltage V1c corresponding to the voltage V1 is restored. The voltage V1c is a voltage that fluctuates by the offset voltage ΔV around the voltage Vs, and it approximately matches the voltage V1.

The DLPF 70 outputs the voltage V5 as the average value of the voltage V4 over the period Td. In other words, the DLPF 70 repeatedly outputs the voltage V5 every period Td. By repeatedly calculating the voltage V5 in this manner, the voltage V5 with the high-frequency components removed from the voltage V4 is obtained. The error voltage Verrc in the voltage V4 is a high frequency component and is therefore removed by the DLPF 70. The voltage V1c of the voltage V4 is the voltage that matches the voltage V1 described above. It is noted that V1=Vs+ΔV. The offset voltage ΔV that constitutes the voltage V1c is a high-frequency component, and thus it is removed by the DLPF 70. The voltage Vs that constitutes the voltage V1c is a DC component, and therefore it is not removed by the DLPF 70. Therefore, the voltage V5 output by DLPF 70 matches the voltage Vs.

As described above, according to the voltage detection circuit 10, it is possible to output a voltage V5 that matches the voltage Vs. The error voltage Verr can be eliminated by the output chopper circuit 60 and the DLPF 70. Additionally, since the offset voltage ΔV is modulated to high-frequency components by the operation of the current chopper circuit 34, the offset voltage ΔV can be eliminated by the DLPF 70. Furthermore, since the frequency fc of the offset voltage ΔV and the frequency fc of the error voltage Verrc are both equal to the output frequency fd of the DLPF 70, no error due to frequency deviation occurs in the DLPF 70. Therefore, according to the voltage detection circuit 10, the voltage Vs can be accurately detected.

In addition, in the first embodiment, since the current chopper circuit 34 operates at the same frequency fc as the input chopper circuit 40 and the output chopper circuit 60, a common pulse signal 90 can be provided to these chopper circuits. Since the frequency signal generation circuit 80 can be shared among each chopper circuit, the voltage detection circuit 10 can be miniaturized.

Next, the disconnection detection by the voltage detection circuit 10 will be explained. If a disconnection occurs at point X in FIG. 1 during the detection operation of the voltage Vs, the first input wiring 20a will be severed from the terminal 12a, and the current I1 will no longer flow from the first input wiring 20a to the terminal 12a. As a result, the first input wiring 20a will be charged by the current I1, causing the potential of the first input wiring 20a to rise suddenly. For example, the capacitor 24c is charged by the current I1, causing the potential of the first input wiring 20a to rise suddenly. For example, the voltage V1 may rise to an excessively high positive voltage. Additionally, although not shown in the drawing, if the second input wiring 20b is cut off from the terminal 12b, the current I2 will no longer flow from the second input wiring 20b to the terminal 12b, causing the voltage V1 to drop suddenly. For example, the voltage V1 may drop to an excessively large negative voltage in absolute value. Therefore, it is possible to detect whether a disconnection has occurred based on the absolute value or the rate of change of the voltage V1. For example, it is possible to detect whether a disconnection has occurred based on the absolute value or the rate of change of the voltage V5, which varies in response to the voltage V1. In this way, the voltage detection circuit 10 can perform the disconnection detection operation in parallel with the detection operation of the voltage Vs. This prevents false detection of voltage Vs in the event of the disconnection.

As described above, according to the voltage detection circuit 10 in the first embodiment, it is possible to accurately detect the voltage Vs while simultaneously detecting the disconnection during the detection operation of the voltage Vs.

### Second Embodiment

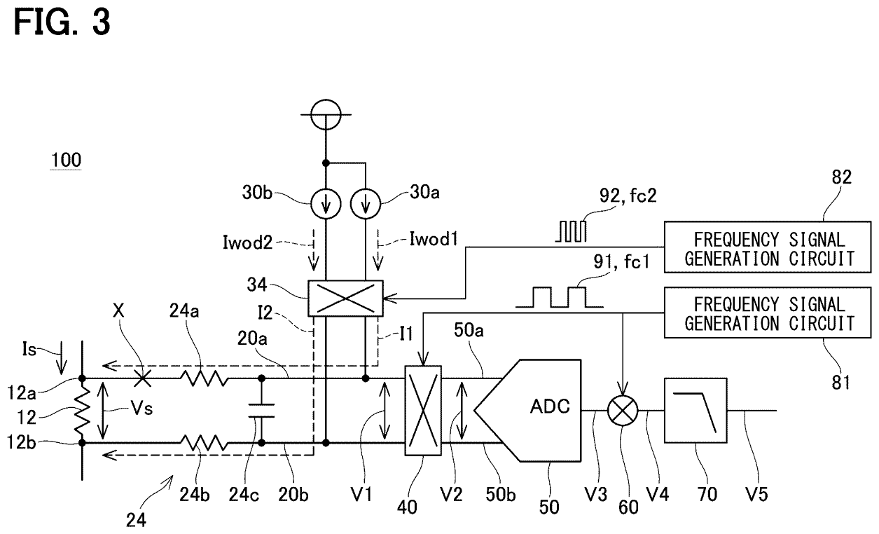

A voltage detection circuit 100 according to a second embodiment shown in FIG. 3 includes two frequency signal generation circuits 81 and 82. The frequency signal generation circuit 81 outputs a pulse signal 91 that oscillates at a frequency fc1. The frequency fc1 is equal to the output frequency fd of the DLPF 70. The duty ratio of the pulse signal 91 is 50%. The frequency signal generation circuit 82 outputs a pulse signal 92 that oscillates at a frequency fc2. The frequency fc2 is four times the output frequency fd of the DLPF 70 (i.e., 2² times). The duty ratio of the pulse signal 92 is 50%. The pulse signal 91 is provided to the input chopper circuit 40 and the output chopper circuit 60. The input chopper circuit 40 and the output chopper circuit 60 operate in synchronization with the pulse signal 91. The pulse signal 92 is provided to the current chopper circuit 34. The current chopper circuit 34 operates in synchronization with the pulse signal 92. Other configurations of the voltage detection circuit 100 in the second embodiment are the same as those of the first embodiment.

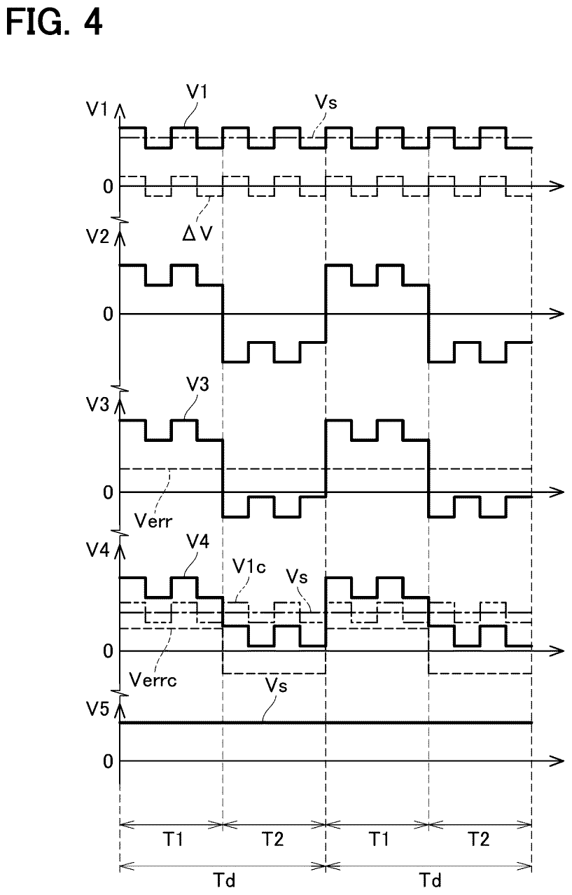

FIG. 4 shows the changes in voltages V1 to V5 during the normal operation of the voltage detection circuit 100 in the second embodiment. In the second embodiment, the current chopper circuit 34 switches the connection state at the frequency fc2, which is four times the output frequency fd. Therefore, the offset voltage ΔV oscillates four times during the period Td. Additionally, since the operating frequency fc1 of the input chopper circuit 40 is equal to the output frequency fd of the DLPF, the input chopper circuit 40 operates in the same manner as in the first embodiment. Therefore, the voltage V2 becomes equal to the voltage V1 during the period T1, and becomes the inverted voltage of V1 during the period T2. Since the ADC 50, similar to Embodiment 1, converts the voltage V2 into a digital value, the voltage V3 becomes the voltage V2 with an error voltage Verr added. The ADC 50, similar to the first embodiment, converts the voltage V2 into a digital value, so the voltage V3 becomes the voltage V2 with an added error voltage Verr. Therefore, the voltage V4 output by the output chopper circuit 60 includes a restored voltage V1c of the voltage V1 and an error voltage Verrc that is the error voltage Verr modulated to a high frequency. The DLPF 70 operates at the output frequency fd, similar to the first embodiment, and removes the high-frequency components from the voltage V4. The error voltage Verrc is removed by the DLPF 70. The high-frequency component (i.e., offset voltage ΔV) in the voltage V1c is also removed by the DLPF 70. Therefore, a voltage that substantially matches the voltage Vs is output as the voltage V5.

As described above, the voltage detection circuit 100 in the second embodiment can also output the voltage V5 that matches the voltage Vs, as in the first embodiment. In the second embodiment, the offset voltage ΔV is modulated to a higher frequency fc2 than in the first embodiment, so the DLPF 70 can further remove the offset voltage ΔV and reduce noise. Additionally, in the second embodiment, similar to first embodiment, the disconnection can be detected during the detection operation of the voltage Vs. Thus, according to the voltage detection circuit 100 in the second embodiment, the voltage Vs can be accurately detected and the disconnection can be detected during the detection operation of the voltage Vs.

If the frequencies fd, fc1, and fc2 satisfy the following relationships when m and n are integers greater than or equal to zero, the voltage Vs can be accurately detected. The relations fc1=fd×2^{m} and fc2=fd×2ⁿ, where n≥m are satisfied. In the first embodiment, m is equal to 0 and n is equal to 0. In the second embodiment, m is equal to 0 and n is equal to 2. In the first and second embodiments, m is 0. However, m may be an integer equal to or greater than 1. In this manner, if the frequencies fc1 and fc2 are greater than or equal to the frequency fd, the offset voltage ΔV and the error voltage Verr can be modulated to a high-frequency band that can be removed by the DLPF 70. Therefore, the offset voltage ΔV and the error voltage Verr can be properly removed. Furthermore, if the frequencies fc1 and fc2 are 2^{m} or 2ⁿ times the frequency fd, it is possible to prevent desynchronization in the processing of the offset voltage ΔV and the error voltage Verr by the DLPF 70, thereby suppressing the occurrence of errors in the DLPF 70. Therefore, if the above relationships are satisfied, the voltage Vs can be accurately detected. The desynchronization may also be referred to as synchronization error.

The connection state A corresponds to a third connection state. The connection state B corresponds to a fourth connection state. The connection state C corresponds to a first connection state. The connection state D corresponds to a second connection state.

Although the embodiments have been described in detail above, these are merely examples and do not limit the scope of claims. The techniques described in the claims include various modifications and modifications of the specific examples illustrated above. The technical elements described in the present specification or the drawings exhibit technical usefulness alone or in various combinations, and are not limited to the combinations described in the claims at the time of filing. In addition, the techniques illustrated in the present specification or drawings achieve multiple objectives at the same time, and achieving one of the objectives itself has technical usefulness.

What is claimed is:

1. A voltage detection circuit comprising:
an AD converter having a first input terminal and a second input terminal, the AD converter configured to convert a voltage applied between the first input terminal and the second input terminal to a digital value;
a first input wiring;
a second input wiring;
an input chopper circuit configured to execute a switchover between a first connection state and a second connection state at a first frequency,
the first connection state being a state in which
the first input wiring is connected to the first input terminal, and
the second input wiring is connected to the second input terminal,
the second connection state being a state in which
the first input wiring is connected to the second input terminal, and
the second input wiring is connected to the first input terminal;
an output chopper circuit configured to alternately execute an inverting operation and a non-inverting operation at the first frequency, the inverting operation being an operation in which an output value of the AD converter is inverted and then output, the non-inverting operation being an operation in which the output value of the AD converter is output without inverting the output value;
a digital low-pass filter configured to remove a high-frequency component from an output value of the output chopper circuit, and be operated at an output frequency,
a first current source;
a second current source; and
a current chopper circuit configured to execute a switchover between a third connection state and a fourth connection state at a second frequency,
the third connection state being a state in which
the first current source is connected to the first input wiring, and
the second current source is connected to the second input wiring,
the fourth connection state being a state in which
the first current source is connected to the second input wiring, and
the second current source is connected to the first input wiring,
wherein
the first frequency is equal to the output frequency multiplied by two raised to power of m, where m is an integer greater than or equal to zero,
the second frequency is equal to the output frequency multiplied by two raised to power of n, where n is an integer greater than or equal to zero, and
n is greater than or equal to m.

2. The voltage detection circuit according to claim 1, wherein
n is equal to m.

3. The voltage detection circuit according to claim 1, wherein
n is larger than m.

4. The voltage detection circuit according to claim 1, further comprising:
a first resistor; and
a second resistor, wherein
the first input wiring is configured to be connected to a voltage detection target device via the first resistor, and
the second input wiring is configured to be connected to the voltage detection target device via the second resistor.

5. The voltage detection circuit according to claim 1, further comprising:
a shunt resistor connected between the first input wiring and the second input wiring.
